(19) United States
(12) Patent Application Publication
(10) Pub. No.: US 2013/0139966 A1
(43) Pub. Date: Jun. 6, 2013

(54) JIG FOR USE IN ETCHING AND CHEMICAL LIFT-OFF APPARATUS INCLUDING THE SAME

(71) Applicants: Su-hee CHAE, Suwon-si (KR); Jun-youn KIM, Suwon-si (KR); Young-soo PARK, Yongin-si (KR); Jae-won LEE, Seoul (KR); Young-jo TAK, Pohang-si (KR); Hyun-gi HONG, Suwon-si (KR)

(72) Inventors: Su-hee CHAE, Suwon-si (KR); Jun-youn KIM, Suwon-si (KR); Young-soo PARK, Yongin-si (KR); Jae-won LEE, Seoul (KR); Young-jo TAK, Pohang-si (KR); Hyun-gi HONG, Suwon-si (KR)

(73) Assignee: Samsung Electronics Co., Ltd., Suwon-Si (KR)

(21) Appl. No.: 13/619,521

(22) Filed: Sep. 14, 2012

(30) Foreign Application Priority Data
Dec. 1, 2011 (KR) 10-2011-0127862

(51) Int. Cl. H01L 21/306

(52) U.S. Cl. 156/345.3

(57) ABSTRACT

A jig for use in etching supports an etching target while an etching process is performed and surrounds a remaining region of the etching target except for a portion of the etching target, so as to expose the portion of the etching target. Accordingly, a stable support of the etching target during the etching process may be provided, and thus an etching of an undesired region may be prevented, and a stable production yield may be accomplished.

### CROSS-REFERENCE TO RELATED APPLICATIONS

This application claims the benefit of Korean Patent Application No. 10-2011-0127862, filed on Dec. 1, 2011, in the Korean Intellectual Property Office, the disclosure of which is incorporated herein in its entirety by reference.

### BACKGROUND

1. Field

The present disclosure relates to a jig for use in etching and/or a chemical lift-off apparatus including the jig.

2. Description of the Related Art

A semiconductor light-emitting device (LED) is a highly efficient and environmentally friendly light source that is used in various fields including displays, optical communications, vehicles, general lightings, or the like. Recently, due to the development of a white-light LED, an LED technology for general lightings has been highlighted. The white-light LED may be formed by using a blue or ultraviolet LED and a phosphor, or by combining red, green, and blue LEDs.

The blue or ultraviolet LED, which is a major element of the white-light LED, is generally formed by using a gallium nitride (GaN)-based compound semiconductor. The GaN-based compound semiconductor has a large bandgap and may obtain light in almost every wavelength region ranging from ultraviolet light to visible light according to its nitride composition.

In general, a thin-film type GaN LED is manufactured by epitaxially growing a GaN-based LED thin film on a sapphire (Al₂O₃) substrate. However, when a GaN-based compound semiconductor is grown as a thin film on the sapphire substrate, emission efficiency deteriorates due to a lattice constant mismatch or a difference between thermal expansion coefficients. In addition, it is difficult to grow the GaN-based compound semiconductor to a larger size and thereby increases manufacturing costs.

Meanwhile, in order to manufacture an LED having a vertical structure to have improved brightness, it is necessary to separate the sapphire substrate and the epitaxially grown GaN-based LED thin film. For the separation process, a laser lift-off (LLO) process may be employed. However, a laser is irradiated during the LLO process such that a heat exceeding a threshold sublimation temperature of Ga is applied to the GaN-based LED thin film. Thus, the GaN-based LED thin film may be damaged and light output may be deteriorated. Also, after the sapphire substrate is separated by using the LLO process, Ga drops may remain in the GaN-based LED thin film and these drops have to be removed in a subsequent process.

In order to solve the aforementioned problems, a new method has been proposed. According to the new method, the GaN-based LED thin film is epitaxially grown on a silicon substrate, instead of on the sapphire substrate. Then, the GaN-based LED thin film is separated from the silicon substrate by using a chemical lift-off (CLO) process. With respect to the silicon substrate, a large wafer having a diameter equal to or greater than 12 inches is desired. The silicon substrate is less susceptible to bending in a high temperature process than the sapphire substrate. Accordingly, the problems of using the sapphire substrate may be solved or reduced by using the silicon substrate. Also, in the CLO process, the substrate is separated by using the chemical etching process to be able to avoid a local overheating problem due to use of the laser. In addition, separating the substrate by using the CLO process is done at relatively lower costs.

However, when the silicon substrate is removed in the CLO process, etching can be performed not only on the silicon substrate but also on a unwanted region. Thus, a surface state of an LED thin film may be defective or the LED thin film may be detached from a supporting layer, and thereby causing a problem on a production yield.

### SUMMARY

Example embodiments of the present inventive concepts provide a jig which has a structure capable of supporting a light-emitting device (LED) structure and reducing or preventing an undesired region of the LED structure from being etched while an etching proceeds using a chemical lift-off (CLO) process.

According to an example embodiment, a CLO apparatus may include the jig.

Additional aspects of the present inventive concepts will be set forth in part in the description which follows and, in part, will be apparent from the description, or may be learned by practice of example embodiments.

According to an example embodiment, a jig for use in etching supports an etching target while an etching process is performed, and surrounds the etching target except for a portion of the etching target, so as to expose the portion of the etching target.

The etching target may be a semiconductor structure having a stack of a support layer, a semiconductor thin film, and a substrate. The jig as described herein may include a frame structure having an etching hole in an upper portion of the frame structure and configured to receive the semiconductor structure and configured to expose a top surface of the substrate; and a sealing member in the frame structure and in configured to seal the semiconductor thin film and the support layer.

The frame structure may include a lower frame configured to support a lower portion of the support layer; an upper frame above the lower frame, having an etching hole formed in a central portion thereof, and configured to support an upper edge of the substrate; and a fastening member configured to fasten the upper frame and the lower frame together and configured to adjust a distance between the upper frame and the lower frame.

The sealing member may be between the upper frame and the lower frame.

The sealing member may include a first sealing member disposed between the semiconductor structure and the upper frame; and a second sealing member disposed between the upper frame and the lower frame.

A width of an overlapping region of the first sealing member with respect to the top surface of the substrate may be about 5 mm or less.

At least one of a cross-section of the first and second sealing members may be an ‘O’-ring shape.

At least one of the upper frame and the lower frame may have a loading groove, which is configured to be coupled to the second sealing member.

The upper frame may have an insertion groove, which is configured to be coupled to the first sealing member.

The insertion groove may be disposed in a region in which the upper frame overlaps with the substrate. Each of the upper frame and the lower frame may define a fastening hole, the fastening hole configured to couple with the fastening member.

The loading groove and the insertion groove may be disposed between the fastening member and the etching hole.

According to an example embodiment, a chemical lift-off apparatus may include the jig as described herein.

According to an example embodiment, a jig supporting an etching target during an etching process may include a frame structure configured to expose an upper portion of an etching target, the frame structure defining an etching opening in an upper portion thereof and configured to hold the etching target, and a sealing member in the frame body, the sealing member configured to seal at least a portion of the etching target.

The frame structure may further include an upper frame defining the etching opening, and a lower frame under the upper frame having a recessed portion, the recessed portion configure to hold the etching target.

The frame structure may further include a fastening member configured to couple the upper frame and the lower frame together, the fastening member adjusting a distance between the upper frame and lower frame.

The sealing member may be vertically between the upper frame and lower frame and may be horizontally between the fastening member and the opening defined in the frame structure.

The frame structure may be configured to receive a semiconductor structure having a stack of a support layer, a semiconductor thin film, and a substrate, and is configured to expose a top surface of the substrate.

The frame structure may include a lower frame configured to support a lower portion of the support layer, an upper frame above the lower frame, the upper frame defining the etching opening and configured to support an upper edge of the substrate, and a fastening member configured to couple the upper frame and lower frame together, the fastening member adjusting a distance between the upper frame and lower frame.

The sealing member may be vertically between the upper frame and lower frame and may be horizontally between the fastening member and the opening defined in the upper frame.

### BRIEF DESCRIPTION OF THE DRAWINGS

Example embodiments of the present inventive concepts will become apparent and more readily appreciated from the following description of the embodiments, taken in conjunction with the accompanying drawings, in which:

FIG. 1 schematically illustrates a chemical lift-off (CLO) process according to an example embodiment;

FIG. 2 schematically illustrates a jig and an etching tank 200, according to an example embodiment;

FIG. 3 is an exploded perspective view that illustrates each of the elements of the jig of FIG. 2;

FIG. 4 is a cross-sectional view of the jig formed by combining the elements of the jig, according to an example embodiment;

FIG. 5 is a cross-sectional view of a jig formed by combining the elements of the jig, according to an example embodiment;

FIG. 6 is a cross-sectional view of a jig formed by combining the elements of the jig, according to an example embodiment;

FIG. 7 is a magnified view illustrating a contact state between a first sealing member and a light-emitting device (LED) structure of FIG. 4;

FIGS. 8A through 8C illustrate operations of the jig, according to an example embodiment;

FIGS. 9A and 9B illustrate states of the LED structure when an etching process is performed by using the jig, according to an example embodiment;

FIG. 10 is an image illustrating a state of the LED structure during a conventional CLO process;

FIG. 11 is an image illustrating a state of the LED structure during a CLO process using the jig, according to an example embodiment; and

FIG. 12 is a conceptual diagram that schematically illustrates an example of a CLO apparatus including the jig for use in etching, according to an example embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements throughout, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

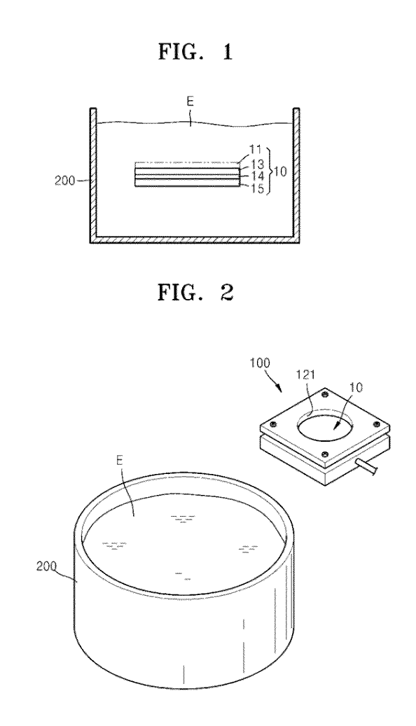

FIG. 1 schematically illustrates a chemical lift-off (CLO) process according to an example embodiment.

Before describing example embodiments of the present inventive concepts, the CLO process will now be briefly described.

Referring to FIG. 1, the CLO process separates a substrate 11 and a semiconductor thin film 13 by wet etching. In the CLO process, a semiconductor structure 10 including the semiconductor thin film 13 epitaxially grown thereon is submerged in an etching solution E such that the substrate 11 may be removed, or, although not illustrated in FIG. 1, a buffer layer disposed between the substrate 11 and the semiconductor thin film 13 may be removed. Accordingly, the substrate 11 may be separated from the semiconductor thin film 13. Before the substrate 11 is separated from the semiconductor thin film 13, a support layer 15 for supporting the semiconductor thin film 13 may be adhered to a surface of the semiconductor thin film 13 by using an adhesion layer 14.

An example embodiment is related to a jig for etching an etching target by the CLO process. The etching target may be the semiconductor structure 10, for example, an LED structure 10 in which the substrate 11, the LED thin film 13, and the support layer 15 are stacked.

The substrate 11 may be used to epitaxially grow the LED thin film 13 thereon. For example, the substrate 11 may be a silicon substrate, taking into account ease of growing a larger size and an emission efficiency of the LED thin film 13 formed of gallium nitride (GaN).

The LED thin film 13 may be epitaxially grown on the substrate 11, and although not illustrated in FIG. 1, the LED thin film 13 may include an n-type semiconductor layer, an active layer, and a p-type semiconductor layer for emission layers.

The n-type semiconductor layer may be arranged on a surface of the substrate 11 and may be formed of a nitride semiconductor doped with an n-type impurity. For example, the n-type semiconductor layer may be formed by doping a semiconductor material with an n-type impurity. The composition of the semiconductor material may be represented by a formula: AlₓIn_{y}Ga_{(1-x-y)}N (where, 0≦x≦1, 0≦y≦1, and 0≦x+y≦1). The nitride semiconductor forming the n-type semiconductor layer may include GaN, AlGaN, InGaN, and the like. The n-type impurity may include Si, Ge, Se, Te, and the like.

The active layer may be disposed between the n-type semiconductor layer and the p-type semiconductor layer and may emit light having a predetermined energy due to a recombination of an electron and a hole. The active layer may be formed of a semiconductor material of a composition represented by a formula: InₓGa₁₋ₓN (where, 0≦x≦1), a bandgap energy of which may be adjusted according to Indium content. Also, the active layer may be a multi-quantum well (MQW) layer formed by alternately stacking a quantum barrier layer and a quantum well layer.

The p-type semiconductor layer may be arranged on the active layer and may be formed of a nitride semiconductor doped with a p-type impurity. For example, the p-type semiconductor layer may be formed by doping a semiconductor material with a p-type impurity. The composition of the semiconductor material may be represented by the general formula: AlₓIn_{y}Ga_{(1-x-y)}N (where, 0≦x≦1, 0≦y≦1, and 0≦x+y≦1). The nitride semiconductor forming the p-type semiconductor layer may include GaN, AlGaN, InGaN, and the like. The p-type impurity may include Mg, Zn, Be, and the like.

When a current or a voltage is applied to a structure in which the n-type semiconductor layer, the active layer, and the p-type semiconductor layer are sequentially stacked, an electron and a hole may combine in the active layer and an energy corresponding to the energy bandgap of the active layer may be emitted in the form of light. In this regard, a stacking order is not limited to the aforementioned stacking order and thus, the layers may be stacked in an order of the p-type semiconductor layer, the active layer, and the n-type semiconductor layer.

The support layer 15 may be directly or indirectly adhered to a surface of the LED thin film 13 and support the LED thin film 13. The support layer 15 may be formed of silicon. In a case where the support layer 15 is formed of silicon, and an etching process is performed on the substrate 11, a portion of the support layer 15 may also be removed because the substrate 11 is formed of the same silicon as the support layer 15. The jig according to the present inventive concept may hamper or prevent this undesired removal and will now be described in detail.

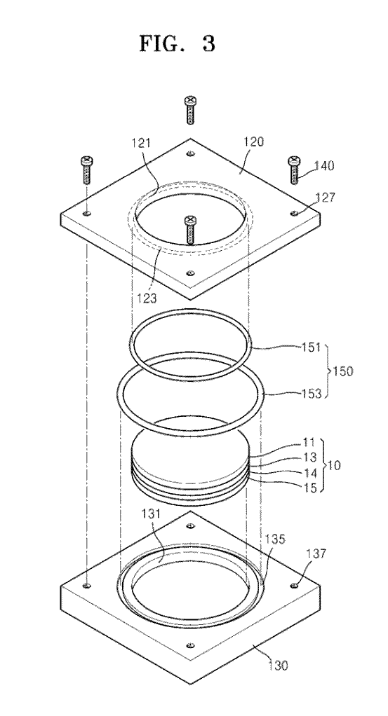

FIG. 2 schematically illustrates a jig 100 and an etching tank 200, according to an example embodiment. FIG. 3 is an exploded perspective view that illustrates each of the elements of the jig 100 of FIG. 2. FIG. 4 is a cross-sectional view of the jig 100 formed by combining the elements of the jig 100.

Referring to FIG. 2, the jig 100 may be submerged in the etching tank 200 storing the etching solution E while the jig 100 supports the LED structure 10. In this manner, the jig 100 supports the LED structure 10 while an etching process is performed. At the same time, the jig 100 may be configured to support the LED structure 10 such that the jig 100 surrounds an LED thin film and a support layer, and exposes the substrate 11 of the LED structure 10.

The jig 100 may include a frame structure 110 and a sealing member 150.

The frame structure 110 may have an etching hole 121 formed in an upper portion of the frame structure 110 and accept the LED structure 10 therein. Because the etching hole 121 is formed in the upper portion of the frame structure 110, only a top portion of the LED structure 10 accepted in the frame structure 110 may be exposed. For example, if the LED structure 10 is disposed with the substrate 11 on top, only a top portion of the substrate 11 may be exposed.

The sealing member 150 may be disposed in the frame structure 110 and seal an inside of the frame structure 110 or a gap between the LED structure 10 and the frame structure 110, and thereby reduces or prevents penetration of the etching solution E.

Referring to FIGS. 3 and 4, the jig 100 may include an upper frame 120, a lower frame 130, a first sealing member 151, a second sealing member 153, and a fastening member 140.

The frame structure 110 may be formed of a plurality of frames that may be separated or combined. As illustrated in FIGS. 3 and 4, the plurality of frames may include the upper frame 120 and the lower frame 130.

The lower frame 130 may contact and/or support a lower portion of the LED structure 10, for example, the support layer 15.

The lower frame 130 may have a position determination groove 131 formed in a central portion of the lower frame 130. Due to the position determination groove 131, when the LED structure 10 is positioned in the lower frame 130, a position of the LED structure 10 may be exactly set.

The upper frame 120 may be disposed above the lower frame 130 and has the etching hole 121 formed in a central portion of the upper frame 120. The upper frame 120 having the etching hole 121 in its central portion may support an upper edge of the LED structure 10, and the remaining region of the substrate 11 except for an upper edge of the substrate 11 may be externally exposed via the etching hole 121.

A diameter of the etching hole 121 formed in the upper frame 120 may be less than a diameter of the accepted LED structure 10.

The LED structure 10 may be disposed between the upper frame 120 and the lower frame 130, the support layer 15 positioned in a lower portion of the LED structure 10 may contact and/or be supported by the lower frame 130, and the substrate 11 positioned in an upper portion of the LED structure 10 may be supported by the upper frame 120 except for its portion externally exposed via the etching hole 121.

The sealing member 150 may include a plurality of sealing members. The plurality of sealing members may maintain the sealing strength of the sealing member 150 while the etching process is performed and may be formed of a material that is resistant to the etching solution E. As illustrated in FIGS. 3 and 4, the sealing member 150 may include the first sealing member 151 and the second sealing member 153.

The first sealing member 151 may be disposed between the LED structure 10 and the upper frame 120. Because the first sealing member 151 is disposed between the LED structure 10 and the upper frame 120 and thus seals a gap therebetween, the first sealing member 151 may reduce or prevent the etching solution E, which flows in the etching hole 121 of the upper frame 120, from penetrating into the gap between the LED structure 10 and the upper frame 120.

Here, the upper frame 120 may have an insertion groove 123 into which a portion of the first sealing member 151 may be inserted. Due to the insertion groove 123, an exact position of the first sealing member 151 may be determined, and thus, penetration of the etching solution E that may be caused by an inexact disposition of the first sealing member 151 may be reduced or prevented. For example, in order to allow the first sealing member 151 to seal the gap between the upper frame 120 and the substrate 11, the insertion groove 123 may be formed in a region where the upper frame 120 overlaps with the substrate 11 when the upper frame 120 approaches the substrate 11.

The second sealing member 153 may be disposed between the upper frame 120 and the lower frame 130. Since the second sealing member 153 is disposed between the upper frame 120 and the lower frame 130 and thus seals a gap therebetween, the second sealing member 153 may hamper or prevent the etching solution E from penetrating into the gap between the upper frame 120 and the lower frame 130.

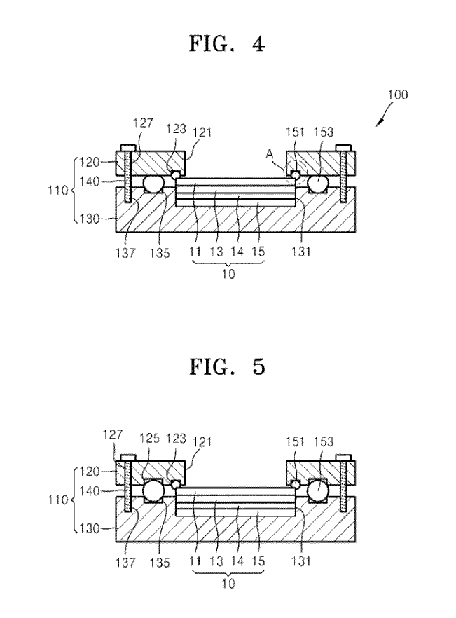

For example, the lower frame 130 may have a loading groove 135 into which a portion of the second sealing member 153 may be inserted. Due to the loading groove 135, not only an exact position of the second sealing member 153 may be determined but also a sealing strength between the upper frame 120 and the lower frame 130 by the second sealing member 153 may be increased. According to the example embodiment, the loading groove 135 may be formed in the lower frame 130. However, a position of the loading groove 135 is not limited thereto. As illustrated in FIG. 5, loading grooves 125 and 135 may be formed in the upper frame 120 and in the lower frame 130, respectively, or the loading groove 125 may be formed only in the upper frame 120. In one embodiment, the loading grooves 125 and 135 may be simultaneously formed in the upper frame 120 and in the lower frame 130, respectively.

For example, the first sealing member 151 may reduce or prevent the etching solution E, which flows in the etching hole 121 of the upper frame 120, from penetrating into the gap between the LED structure 10 and the upper frame 120. Also, the second sealing member 153 may reduce or prevent the etching solution E from penetrating into the gap between the upper frame 120 and the lower frame 130. Also, the insertion groove 123 and the loading groove 135 may be formed to allow the first sealing member 151 and the second sealing member 153 to be correctly positioned, respectively.

The fastening member 140 may connect and/or fasten the upper frame 120 and the lower frame 130 together and adjust a distance between the upper frame 120 and the lower frame 130.

The fastening member 140 may have various structures configured to connect and/or fasten the upper frame 120 and the lower frame 130 together. As illustrated in FIGS. 3 and 4, the fastening member 140 may adjust the distance between the upper frame 120 and the lower frame 130 by being screwed in fastening holes 127 and 137, which are formed in the upper frame 120 and the lower frame 130, respectively. For example, by screwing the fastening member 140, the distance between the upper frame 120 and the lower frame 130 may be decreased so that the upper frame 120 and the lower frame 130 approach each other. As the distance between the upper frame 120 and the lower frame 130 is decreased, the first sealing member 151 and the second sealing member 153 disposed between the upper frame 120, the lower frame 130, and the LED structure 10 may be pressed, and thus the etching solution E may be reduced or prevented from flowing into the rest of the configuration except for the exposed substrate 11.

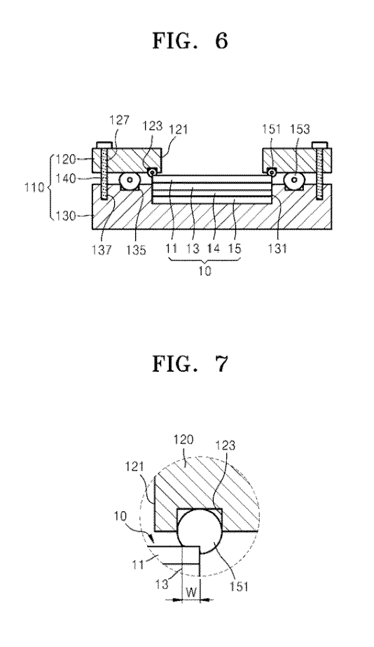

For example, the first and second sealing members 151 and 153 may have elasticity so as to be pressed by a pressing power of the upper frame 120 and the lower frame 130. Also, as illustrated in FIG. 6, a cross-section of the first and second sealing members 151 and 153 may be an ‘O’-ring shape. However, the cross-section of the first and second sealing members 151 and 153 is not limited thereto and thus may have various shapes. The fastening member 140 may be disposed in the sealing member 150. For example, the fastening member 140 may be disposed at an outer side of the second sealing member 153. Accordingly, the second sealing member 153 may maintain its sealing strength, regardless of the flow of the etching solution E via the fastening holes 127 and 137.

The fastening member 140 may include a plurality of fastening members that may be disposed at regular intervals so as to apply a constant pressing power between the upper frame 120 and the lower frame 130. As illustrated in FIG. 3, four fastening members 140 may be disposed at an interval of 90 degree.

FIG. 7 is a magnified view illustrating a contact state between the first sealing member 151 and the LED structure 10 of FIG. 4. Referring to FIG. 7, the first sealing member 151 may press and/or seal an upper portion of the accepted LED structure 10. For example, the first sealing member 151 may contact the upper portion of the accepted LED structure 10, e.g., the first sealing member 151 contacts the substrate 11. A region of the substrate 11 contacting the first sealing member 151 is not exposed to the etching solution E, and thus the region of the substrate 11 may not be removed during the etching process. Because the unremoved region decreases usability of a product, a width W of the region may be equal to or less than 5 mm in consideration of a production yield.

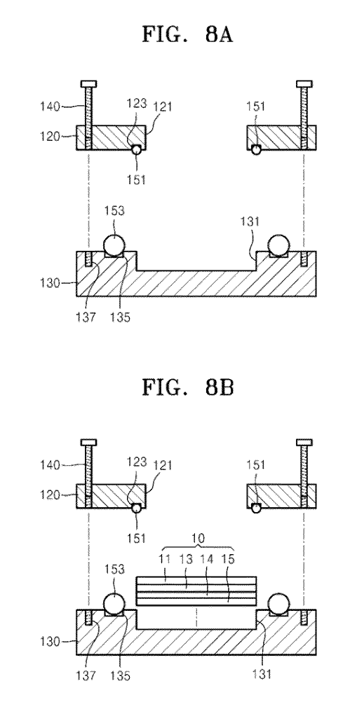

FIGS. 8A through 8C illustrate operations of the jig, according to an example embodiment.

First, referring to FIG. 8A, the upper frame 120 and the lower frame 130 may be disposed with a sufficient distance therebetween so as to allow an etching target, e.g., the LED structure 10, to be disposed therebetween. For example, the first sealing member 151 may be arranged in the insertion groove 123 of the upper frame 120, and the second sealing member 153 may be arranged in the loading groove 135 of the lower frame 130.

Next, as illustrated in FIG. 8B, the LED structure 10 may be disposed between the upper frame 120 and the lower frame 130, which are separate from each other by a sufficient distance, and for example, as disposing the substrate 11 toward the upper frame 120. By disposing the substrate 11 toward the upper frame 120 in which the etching hole 121 is formed, most of a top surface 11a of the substrate 11 may be externally exposed via the etching hole 121. For example, the LED structure 10 may be disposed in the position determination groove 131 formed in the lower frame 130. Accordingly, the LED structure 10 may be disposed at an exact target position of the LED structure 10.

Then, the upper frame 120 and the lower frame 130 may be connected and/or fastened by using the fastening member 140. The fastening member 140 may be connected and/or fastened to the fastening hole 137 of the lower frame 130 and the fastening hole 127 of the upper frame 120. For example, a screw may be used as the fastening member 140, and in this case, the upper frame 120 and the lower frame 130 may approach each other by screwing the fastening member 140. The first sealing member 151 disposed between the upper frame 120 and the LED structure 10 may be pressed due to its elasticity, and thus the first sealing member 151 may reduce or prevent the etching solution E from flowing into a gap between the upper frame 120 and the lower frame 130.

As described above, according to the operations of the upper frame 120 and the lower frame 130 capable of being separated or combined, the fastening member 140 for fastening them together, and the first and second sealing members 151 and 153 for sealing the upper and lower frames 120 and 130 and the LED structure 10, the LED structure 10 may be sealed except for the top surface 11a of the substrate 11. Accordingly, etching of the sealed regions of the LED structure 10 may be reduced or prevented.

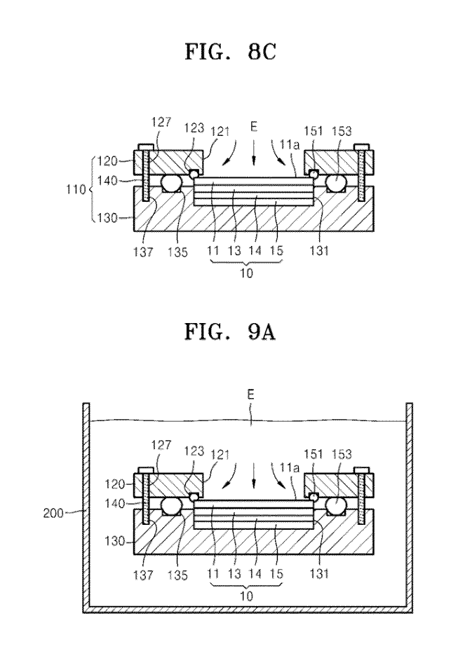

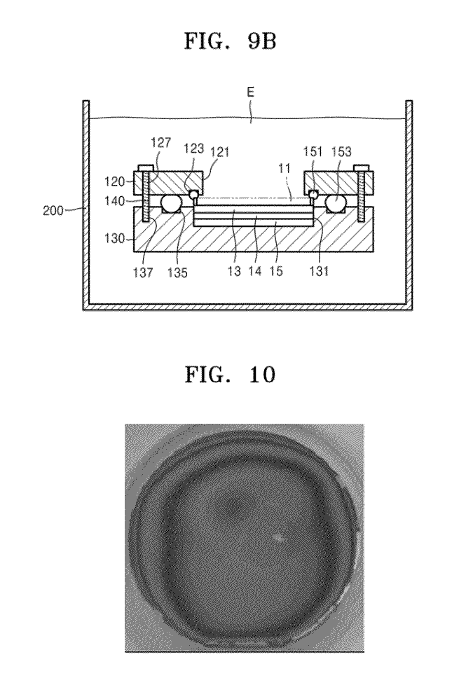

FIGS. 9A and 9B illustrate states of the LED structure 10 when an etching process is performed by using the jig 100, according to an example embodiment.

FIG. 9A illustrates a state of the LED structure 10 supported by the jig 100 before the LED structure 10 is etched. FIG. 9B illustrates a state of the LED structure 10 supported by the jig 100 after the LED structure 10 is etched. The surfaces of the LED structure 10 may be sealed by the frame structure 110 and the first and second sealing members 151 and 153 except for the top surface 11a of the substrate 11, and thus only the top surface 11a of the substrate 11 may be exposed to the etching solution E. Accordingly, the top surface 11a of the substrate 11 may react with the etching solution E, and only the substrate 11 formed of, for example, silicon may be removed by the etching. In the jig 100 according to the example embodiment, the rest of surfaces of the LED structure 10 may be sealed and/or protected by the first and second sealing members 151 and 153. Accordingly, although etching is further performed than a predefined time, an undesired etching of the support layer 15 disposed in a lower portion of the LED structure 10 may be reduced or prevented.

FIG. 10 is an image illustrating a state of the LED structure 10 during a conventional CLO process and FIG. 11 is an image illustrating a state of the LED structure 10 during a CLO process using the jig according to an example embodiment.

According to the related art, the LED structure 10 itself may be submerged in the etching solution E so as to etch the substrate 11. By doing so, all surfaces of the LED structure 10 may be exposed to the etching solution E. Thus, not only the substrate 11 of the LED structure 10 but also the LED thin film 13 and the support layer 15 supporting the LED thin film 13 may also be exposed to the etching solution E. Accordingly, not only the adhesion layer 14 between the LED thin film 13 and the support layer 15 but also an interface of each layer of the LED structure 10 may be etched. As a result, as illustrated in FIG. 10, cracks may occur in a surface of the LED structure 10, for example, in a side portion of the LED structure 10.

In contrast, in a case where etching is performed by using the jig 100 that seals the LED thin film 13 and the support layer 15 and does not seal the substrate 11, occurrence of cracks may be reduced or prevented not only in the adhesion layer 14 between the LED thin film 13 and the support layer 15 but also in an interface of each layer of the LED structure 10. Thus, as illustrated in FIG. 11, cracks may not occur at least in the LED thin film 13.

Therefore, using the jig 100 according to the present inventive concepts may reduce or prevent undesired etching of the LED structure, and thus may result in the LED structure 10 having an improved surface state.

Also, a CLO apparatus 1000, according to the present inventive concepts, may include the jig 100.

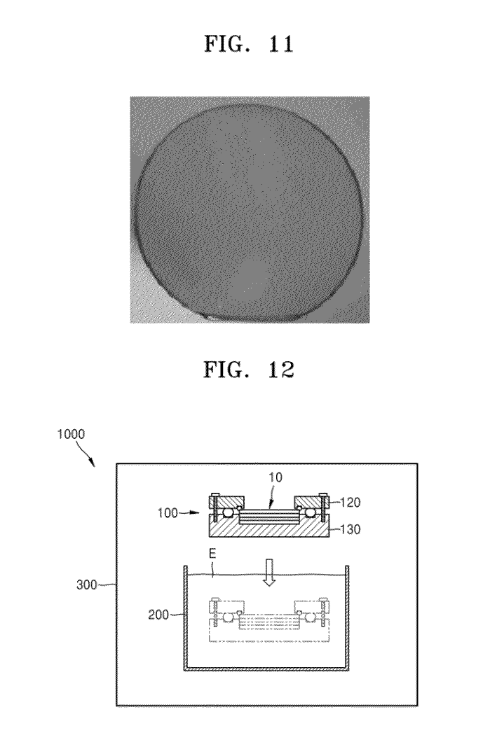

FIG. 12 is a schematic diagram that schematically illustrates an example of the CLO apparatus 1000 including the jig 100, according to an example embodiment. Referring to FIG. 12, the CLO apparatus 1000 may include the jig 100, the etching tank 200, and a chamber 300.

The etching tank 200 may be arranged in the chamber 300 and may be filled with an etching solution E for etching the substrate 11.

The jig 100 may be submerged in the etching tank 200 containing the etching solution E, and then etching may be performed for a desirable (or, alternatively predetermined) time. The jig 100 may the same jig as described above, and thus, a detailed description thereof is omitted.

In the example embodiment of FIG. 12, the jig 100 is submerged in the etching tank 200 while the upper frame 120 having the etching hole 121 is upwardly disposed, but embodiments are not limited thereto. The jig 100 may be submerged while the upper frame 120 is downwardly disposed or is sidewardly disposed.

In the LED structure 10 accepted in the jig 100 and submerged into the etching solution E as aforementioned, only the substrate 11 may be removed.

As described above, the jig 100 accepting the LED structure 10, and the CLO apparatus 1000 including the jig 100 according to the one or more example embodiments are shown along with the accompanied drawings.

According to the present inventive concepts, the jig may stably support the LED structure while etching is performed to remove the substrate from the LED thin film. Also, by preventing the LED structure from being exposed, except for the substrate, etching of the adhesion layer between the LED thin film and the support layer and/or the interface between each of the layers of the LED structure may be reduced or prevented. Accordingly, a production yield of the LED structure may be stabilized.

While example embodiments have been particularly shown and described, it will be understood by one of ordinary skill in the art that variations in form and detail may be made therein without departing from the spirit and scope of the inventive concepts defined by the following claims.

What is claimed is:

1. A jig for use in etching that supports an etching target while an etching process is performed and that surrounds the etching target except for a portion of the etching target.

2. The jig of claim 1 comprising:
a frame structure having an etching hole in an upper portion of the frame structure, the frame structure configured to receive a semiconductor structure having a stack of a support layer, a semiconductor thin film, and a substrate, and the frame structure configured to expose a top surface of the substrate; and
a sealing member in the frame structure, the sealing member configured to seal at least one of the semiconductor thin film and the support layer.

3. The jig of claim 2, wherein the frame structure comprises:
a lower frame configured to support a lower portion of the support layer;
an upper frame above the lower frame, the upper frame having an etching hole in a central portion thereof and configured to support an upper edge of the substrate; and
a fastening member configured to fasten the upper frame and the lower frame together, the fastening member configured to adjust a distance between the upper frame and the lower frame.

4. The jig of claim 3, wherein the sealing member is between the upper frame and the lower frame.

5. The jig of claim 4, wherein the sealing member comprises:
a first sealing member between the semiconductor structure and the upper frame; and
a second sealing member between the upper frame and the lower frame.

6. The jig of claim 5, wherein a width of an overlapping region of the first sealing member with respect to the top surface of the substrate is about 5 mm or less.

7. The jig of claim 5, wherein at least one of a cross-section of the first and second sealing members is an ‘O’-ring shape.

8. The jig of claim 5, wherein at least one of the upper frame and the lower frame has a loading groove, the loading groove configured to be coupled to the second sealing member.

9. The jig of claim 5, wherein the upper frame has an insertion groove, the insertion groove configured to be coupled to the first sealing member.

10. The jig of claim 9, wherein the insertion groove is in a region in which the upper frame overlaps with the substrate.

11. The jig of claim 3, wherein each of the upper frame and the lower frame defines a fastening hole, the fastening hole configured to couple with the fastening member

12. The jig of claim 11, wherein the loading groove and the insertion groove are disposed between the fastening member and the etching hole.

13. A chemical lift-off apparatus comprising the jig of claim 1.

14. A jig supporting an etching target during an etching process, the jig comprising:
a frame structure configured to expose an upper portion of an etching target, the frame structure defining an etching opening in an upper portion thereof and configured to hold the etching target; and
a sealing member in the frame body, the sealing member configured to seal at least a portion of the etching target.

15. The jig of claim 14, wherein the frame structure comprises:
an upper frame defining the etching opening; and
a lower frame under the upper frame having a recessed portion, the recessed portion configure to hold the etching target.

16. The jig of claim 15, wherein the frame structure further comprises:
a fastening member configured to couple the upper frame and the lower frame together, the fastening member adjusting a distance between the upper frame and lower frame.

17. The jig of claim 16, wherein the sealing member is vertically between the upper frame and lower frame and is horizontally between the fastening member and the opening defined in the frame structure.

18. The jig of claim 14, wherein the frame structure is configured to receive a semiconductor structure having a stack of a support layer, a semiconductor thin film, and a substrate, and is configured to expose a top surface of the substrate.

19. The jig of claim 18, wherein the frame structure comprises: a lower frame configured to support a lower portion of the support layer;
an upper frame above the lower frame, the upper frame defining the etching opening and configured to support an upper edge of the substrate; and
a fastening member configured to couple the upper frame and lower frame together, the fastening member adjusting a distance between the upper frame and lower frame.

20. The jig of claim 19, wherein the sealing member is vertically between the upper frame and lower frame and is horizontally between the fastening member and the opening defined in the upper frame.
